(19) United States
(12) Patent Application Publication
(10) Pub. No.: US 2015/0208505 A1
(43) Pub. Date: Jul. 23, 2015

(54) COMBINATION OF A FLEXIBLE PRINTED CIRCUIT BOARD AND A RIGID PRINTED CIRCUIT BOARD AND METHOD OF MAKING THE SAME

(71) Applicant: KEEPER TECHNOLOGY CO., LTD., New Taipei City (TW)

(72) Inventors: Jyun-Syu SHEN, New Taipei City (TW); Chien-Hui LEE, New Taipei City (TW); Shih-Ping HSIAO, New Taipei City (TW)

(73) Assignee: KEEPER TECHNOLOGY CO., LTD., New Taipei City (TW)

(21) Appl. No.: 14/161,634

(22) Filed: Jan. 22, 2014

(51) Int. Cl. H05K 1/14; B23K 1/00; H05K 3/36; H05K 1/02; H05K 3/46

(52) U.S. Cl. CPC H05K 1/144; H05K 1/14; H05K 1/028; H05K 3/4691; H05K 3/363; B23K 1/0016; B23K 2001/12

(57) ABSTRACT

A method of making a combination of a flexible printed circuit board (FPCB) and a rigid printed circuit board (RPCB), comprising steps of providing a RPCB; providing a FPCB having a panel and a hole formed through the FPCB; forming a solder layer located at the hole and between the RPCB and the FPCB; heating through the hole to melt the solder layer; and removing the heat source to solidify the solder layer to obtain a combination of the FPCB and the RPCB. Based on the steps above, there is no need to use any additional connection piece and fixture of the same and the manufacture cost is lowered. In addition, as a result that the solder layer is very thin, the combination made by the method accommodates less space and has extensive applicability.

### BACKGROUND OF THE INVENTION

1. Field of the Invention

The present invention relates to a combination of two printed circuit boards and a method of making the same; particularly relates to a combination of a flexible printed circuit board (FPCB) and a rigid printed circuit board (RPCB) and a method of making the same.

2. Description of the Prior Art(s)

With reference to FIG. 11, in conventional application of printed circuit boards, a combination of a flexible printed circuit board 60 and a rigid printed circuit board 70 is made by using a male and female buckle assembly.

Firstly, a male buckle 80 of the male and female buckle assembly is riveted on the flexible printed circuit board 60 by a fixture and comprises a conductive part. The conductive part of the male buckle 80 is welded to the flexible printed circuit board 60 and the male buckle 80 is electrically connected to the flexible printed circuit board 60.

Secondly, a female buckle 90 of the male and female buckle assembly is riveted on the rigid printed circuit board 70 by a fixture and comprises a conductive part. The conductive part of the female buckle 90 is welded to the rigid printed circuit board 70 and the female buckle 90 is electrically connected to the rigid printed circuit board 70.

Thirdly, the male buckle 80 and the female buckle 90 are buckled to each other while the conductive part of the male buckle 80 is connected to the conductive part of the female buckle 90. Therefore, the flexible printed circuit board 60 and the rigid printed circuit board 70 are combined with each other as a whole by the male buckle 80 and the female buckle 90. In addition, the flexible printed circuit board 60 and the rigid printed circuit board 70 are electrically connected by the conductive part of the male buckle 80 and the conductive part of the female buckle 90.

However, using the male and female buckle assembly incurs additional expenses including the purchase of the male and female buckle assembly and the purchase of a fixture with a particular specification corresponding to the male and female buckle assembly, thus causing a substantial increase in manufacture cost of the combination of the flexible printed circuit board 60 and the rigid printed circuit board 70.

In addition, the male and female buckle assembly has a certain volume. After the male and female buckle assembly is mounted on the flexible printed circuit board 60 and the rigid printed circuit board 70, the combined volume of the flexible printed circuit board 60 and the volume of the rigid printed circuit board 70 increase. Especially, after the flexible printed circuit board 60 and the rigid printed circuit board 70 are combined with each other as a whole, the thickness of the combination of the flexible printed circuit board 60 and the rigid printed circuit board 70 increases significantly. A large space is thus needed to accommodate the combination. Consequently, the application of the combination is restricted.

To overcome the shortcomings, the present invention provides a combination of a flexible printed circuit board and a rigid printed circuit board and a method of making the same to mitigate or obviate the aforementioned problems.

### SUMMARY OF THE INVENTION

The main objective of the present invention is to provide a method of making a combination of a flexible printed circuit board and a rigid printed circuit board that has low manufacture cost. The combination made by the method accommodates less space and has an extensive applicability.

In the method of making a combination of a flexible printed circuit board and a rigid printed circuit board in accordance with the present invention, a rigid printed circuit board having a panel is provided. A flexible printed circuit board having a panel and a hole formed through the panel is also provided. The panel of the flexible printed circuit board has a first side surface and a second side surface. In addition, a solder layer is formed at the hole and between the panel of the rigid printed circuit board and the first side surface of the panel of the flexible printed circuit board. Then, a heat source is formed on the second side surface of the panel of the flexible printed circuit board to melt the solder layer through the hole. After the heat source is removed, the melted solder layer solidifies and the combination of the flexible printed circuit board and the rigid printed circuit board is obtained.

The combination of a flexible printed circuit board and a rigid printed circuit board in accordance with the present invention comprises a rigid printed circuit board having a panel; a flexible printed circuit board having a panel and a hole formed through the panel of the flexible printed circuit board, wherein the panel of the flexible printed circuit board has a first side surface and a second side surface; and a solder layer solidified between the panel of the rigid printed circuit board and the first side surface of the panel of the flexible printed circuit board, wherein the solder layer is located at the hole of the flexible printed circuit board.

In accordance with the present invention, by the forming of the hole, the heat from the heat source is transmitted through the hole and arrives at the solder layer located between the flexible printed circuit board and the rigid printed board to melt the solder layer. After the heat source is removed, the melted solder layer solidifies, and the flexible printed circuit board and the rigid printed circuit board combine with each other as a whole. In this way, there is no need to use any additional connection piece and a fixture of the same and the manufacture cost is lowered. In addition, as a result that the solder layer is very thin, the combination made by the method accommodates less space and has extensive applicability.

Other objectives, advantages and novel features of the invention will become more apparent from the following detailed description when taken in conjunction with the accompanying drawings.

### BRIEF DESCRIPTION OF THE DRAWINGS

FIG. 1 is a flow diagram of a first embodiment of a method of making a combination of a flexible printed circuit board and a rigid printed circuit board in accordance with the present invention;

FIG. 2 is an enlarged side view in partial section of a first embodiment of a combination of a flexible printed circuit board and a rigid printed circuit board in accordance with the present invention;

FIG. 3 is an enlarged side view in partial section of the step of forming a solder layer of the method in FIG. 1;

FIG. 4 is an enlarged side view in partial section of the step of forming a heat source of the method in FIG. 1;

FIG. 5 is a flow diagram of a second embodiment of a method of making a combination of a flexible printed circuit board and a rigid printed circuit board in accordance with the present invention;

FIG. 6 is an enlarged side view in partial section of a second embodiment of a combination of a flexible printed circuit board and a rigid printed circuit board in accordance with the present invention;

FIG. 7 is a flow diagram of a third embodiment of a method of making a combination of a flexible printed circuit board and a rigid printed circuit board in accordance with the present invention;

FIG. 8 is an enlarged side view in partial section of the step of removing the heat source to solidify the solder layer of the method in FIG. 7;

FIG. 9 is an enlarged side view in partial section of the step of forming a strengthened portion of the method in FIG. 7;

FIG. 10 is an enlarged side view in partial section of a third embodiment of a combination of a flexible printed circuit board and a rigid printed circuit board in accordance with the present invention; and

FIG. 11 is an enlarged side view in partial section of a conventional circuit board in accordance with the prior art.

### DETAILED DESCRIPTION OF THE PREFERRED EMBODIMENTS

### Embodiment 1

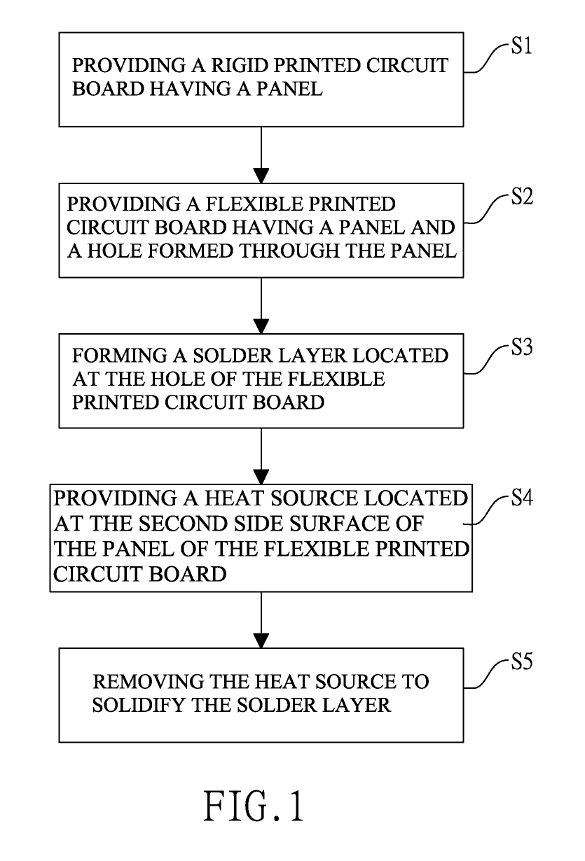

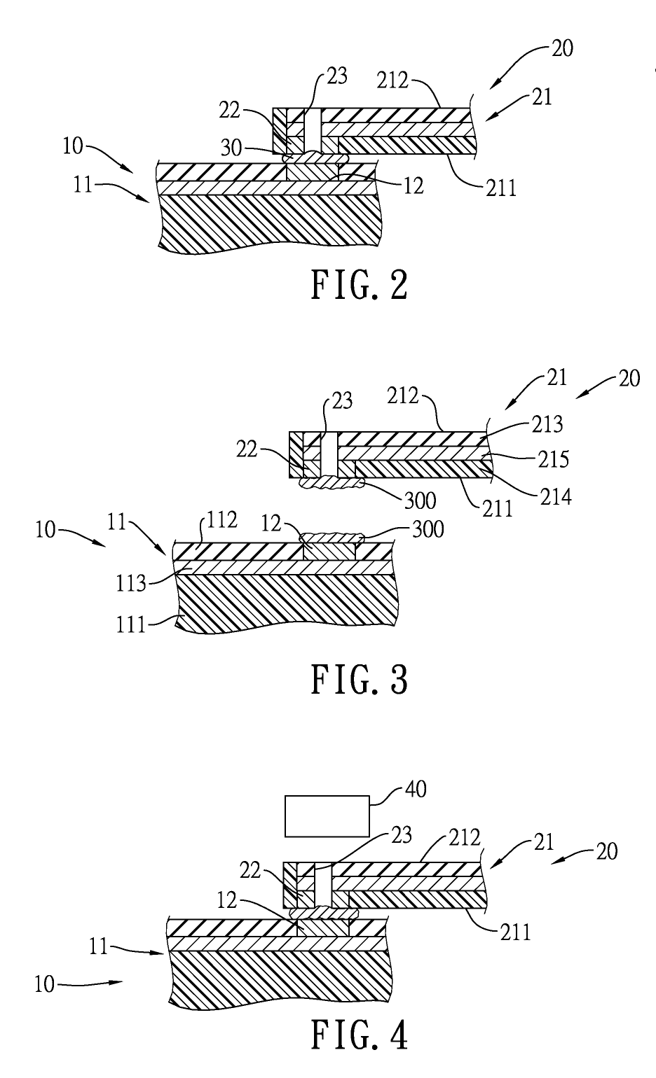

With reference to FIGS. 1 and 2, a method of making a combination of a flexible printed circuit board and a rigid printed circuit board in accordance with the present invention comprises the following steps.

With reference to FIGS. 1 and 3, a rigid printed circuit board 10 with a panel 11 is provided (S1). The rigid printed circuit board 10 provided has a pad 12 located on the panel 11. The panel 11 has a rigid substrate 111, an insulated layer 112 and a conductive layer 113. The conductive layer 113 is attached to the rigid substrate 111. The insulated layer 12 is attached to the conductive layer 113. The pad 12 is attached to the conductive layer 113 and electrically connects to the conductive layer 113. A side edge of the pad 12 connects to the insulated layer 112.

With reference to FIGS. 1 and 3, a flexible printed circuit board 20 with a panel 21 and a hole 23 formed through the panel 21 is provided (S2). The flexible printed circuit board 20 provided has a primary pad 22. The panel 21 of the flexible printed circuit board 20 has a first side surface 211 and a second side surface 212. The primary pad 22 is attached to the first side surface 211. The hole 23 is formed through the panel 21 and the primary pad 22. Further, the panel 21 has a flexible substrate 213, an insulated layer 214 and a primary conductive layer 215. Two side surfaces of the primary conductive layer 215 respectively connect to the flexible substrate 213 and the insulated layer 214. The primary pad 22 is attached to the primary conductive layer 215 and electrically connects to the primary conductive layer 215. A side edge of the primary pad 22 connects to the insulated layer 214.

With reference to FIGS. 1, 3 and 4, a solder layer 30 is formed at the hole 23 of the flexible printed circuit board 20 and between the panel 11 of the rigid printed circuit board 10 and the first side surface 211 of the panel 21 of the flexible printed circuit board 20 (S3). Further, the solder layer 30 is formed between the pad 12 of the rigid printed circuit board 10 and the primary pad 22 of the flexible printed circuit board 20. In addition, the solder layer 30 can be formed by coating solder 300 on the primary pad 22 or/and the pad 12 and attaching the rigid printed circuit board 10 with the flexible printed circuit board 20.

With reference to FIGS. 1 and 4, a heat source 40 is provided at the second side surface 212 of the panel 21 of the flexible printed circuit board 20 to melt the solder layer 30 through the hole 23 (S4).

With reference to FIGS. 1, 2 and 4, the heat source 40 is removed and the solder layer 30 is solidified to obtain a combination of the flexible printed circuit board and the rigid printed circuit board (S5).

According to the method mentioned above, by the forming of the hole 23, the heat from the heat source 40 is transmitted through the hole 23 and arrives at the solder layer 30 located between the flexible printed circuit board 20 and the rigid printed circuit board 10. Thus, the solder layer 30 acquires a sufficient heat to melt. After removing the heat source 40, the melted solder layer 30 solidifies, and the flexible printed circuit board 20 and the rigid printed circuit board 10 combine with each other as a whole. In this way, there is no need to use any additional connection piece and a fixture of the same. Also, the manufacture cost is lowered. Besides, as a result that the solder layer 30 is thin, the combination made by the method accommodates small space. Therefore, the application of the combination is not limited by size or space and the combination can be applied to products that are light, thin, slim, or small.

Moreover, the pad 12 of the rigid printed circuit board 10 and the primary pad 22 of the flexible printed circuit board 20 may be omitted. The solder layer 30 directly connects to the conductive layer 113 and the insulated layer 112 of the rigid printed circuit board 10 while the solder layer 30 directly connects to the primary conductive layer 215 and the insulated layer 30 of the flexible printed circuit board 20.

### Embodiment 2

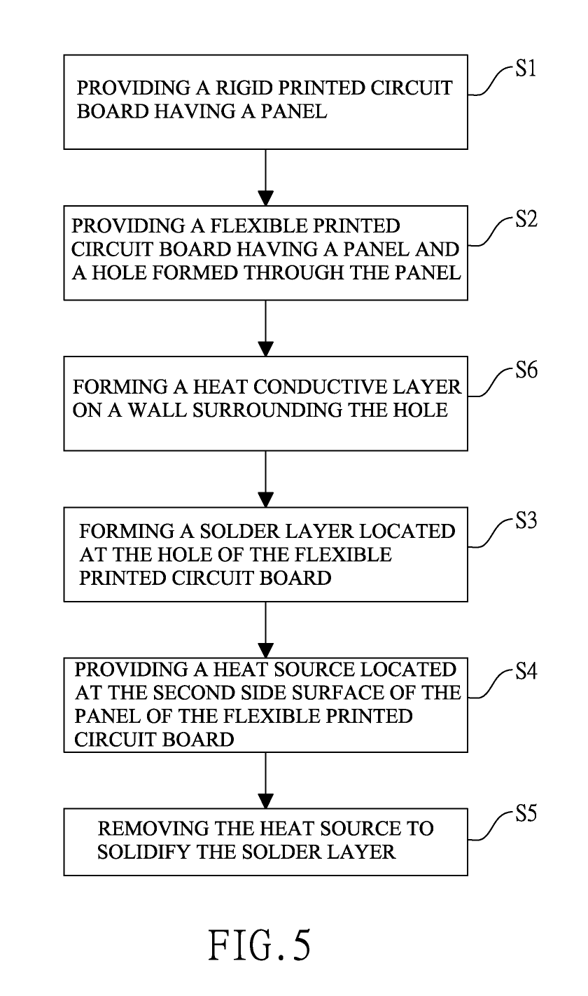

In embodiment 2, with reference to FIG. 5, the method of making a combination of a flexible printed circuit board and a rigid printed circuit board in accordance with the present invention further comprises a step of forming a heat conductive layer on a wall surrounding the hole (S6).

The step of forming a heat conductive layer on a wall surrounding the hole (S6) is between the step of providing a flexible printed circuit board having a panel and a hole formed through the panel (S2) and the step of forming a solder layer located at the hole of the flexible printed circuit board and between the panel of the rigid printed circuit board and the first side surface of the panel of the flexible printed circuit board (S3).

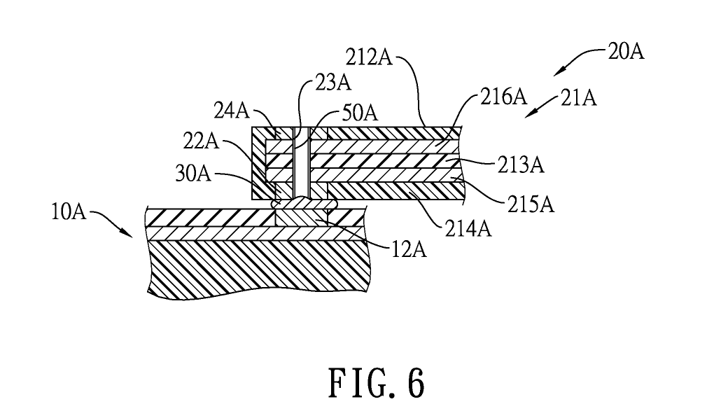

With reference to FIG. 6, in the step of providing a flexible printed circuit board having a panel and a hole formed through the panel, (S2), a secondary pad 24A is attached to the second side surface 212A of the panel 21A of the flexible printed circuit board 20A. The hole 23A is formed through the panel 21A, the primary pad 22A and the secondary pad 24A. Further, the panel 21A has a secondary conductive layer 216A. The primary conductive layer 215A and the secondary conductive layer 216A are respectively attached on two opposite surfaces of the flexible substrate 213A. The insulated layer 214A wraps the flexible substrate 213A, the primary conductive layer 215A, and the secondary conductive layer 216A. The secondary pad 24A is attached to the secondary conductive layer 216A electrically connecting to the secondary conductive layer 215A. A side edge of the secondary pad 24A connects to the insulated layer 214A.

With reference to FIG. 6, in the step of forming a heat conductive layer on a wall surrounding the hole (S6), a heat conductive layer 50A is electroplated on the wall surrounding the hole 23A. Two ends of the heat conductive layer 50A respectively connect to the primary pad 22A and the secondary pad 24A. In a preferred embodiment, the heat conductive layer is made of copper or alloy thereof.

With reference to FIG. 6, in the step of forming a solder layer located at the hole of the flexible printed circuit board and between the panel of the rigid printed circuit board and the first side surface of the panel of the flexible printed circuit board (S3), the solder layer 30A is formed between the pad 12A and the primary pad 22A of the flexible printed circuit board and connects with the heat conductive layer 50A via the primary pad 22A.

With reference to FIG. 6, in the step of providing a heat source located at the first side surface of the panel of the flexible printed circuit board to heat through the hole and melt the solder layer (S4), the heat source is located at the outer side of the secondary pad 24A.

According to the method mentioned above, with reference to FIG. 6, in addition to heat transmission through the hole 23A, the heat from the heat source is also transmitted through the secondary pad 24A and the heat conductive layer 50A; therefore, the heat is rapidly transmitted to facilitate a fast and uniform melting of the solder layer 30A. Accordingly, the fabrication time is shortened. Besides, as the melting of the solder layer 30A is fast and uniform, an incomplete melting of the solder layer 30A is prevented, and then the bonding strength between the flexible printed circuit board 20A and the rigid printed circuit board 10A is reinforced.

### Embodiment 3

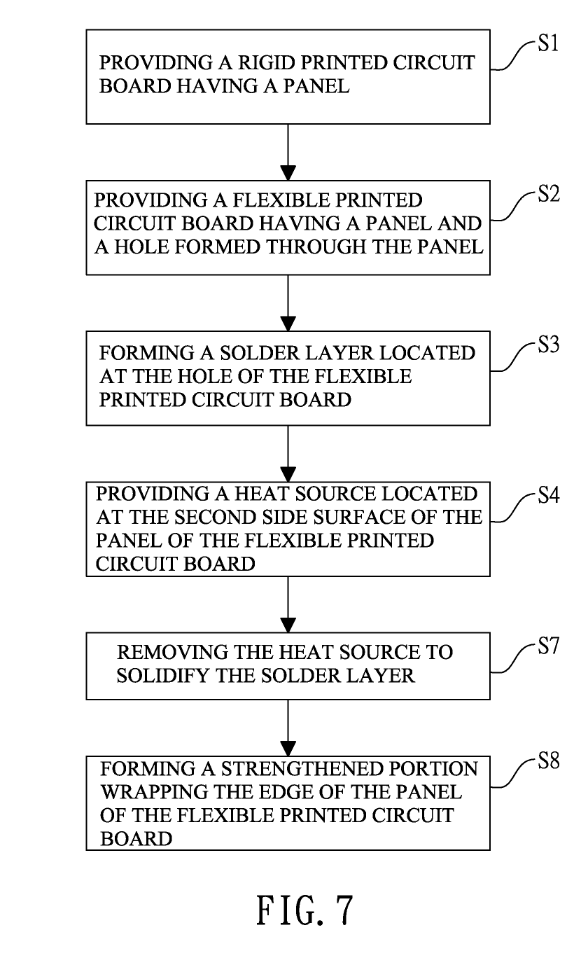

With reference to FIG. 7, a method of making a combination of a flexible printed circuit board and a rigid printed circuit board in accordance with the present invention further comprises the steps of removing the heat source to solidify the solder layer (S7) and forming a strengthened portion wrapping an edge of the panel of the flexible printed circuit board to obtain the combination of the flexible printed circuit board and the rigid printed circuit board (S8). The steps of removing the heat source to solidify the solder layer (S7) and forming a strengthened portion wrapping the edge of the panel of the flexible printed circuit board to obtain the combination of the flexible printed circuit board and the rigid printed circuit board (S8) are after the step of providing a heat source located at the second side surface of the panel of the flexible printed circuit board (S4).

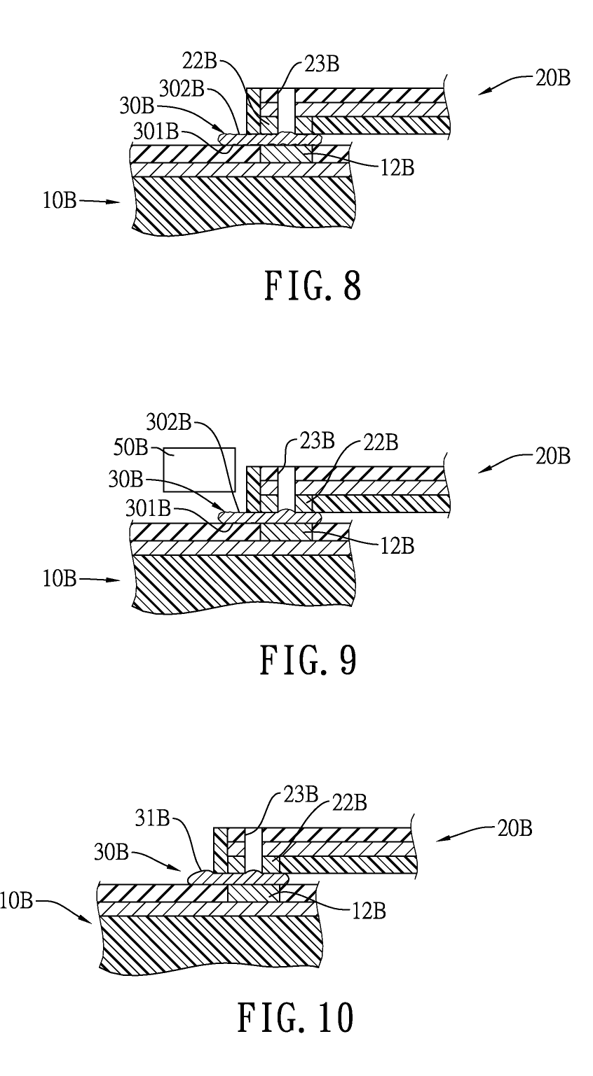

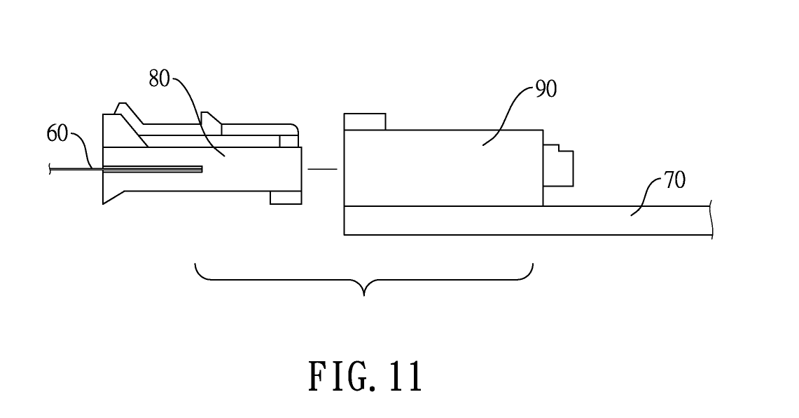

With reference to FIGS. 7 and 8, in the step of forming a solder layer located at the hole of the flexible printed circuit board and between the panel of the rigid printed circuit board and the first side surface of the panel of the flexible printed circuit board (S3), the solder layer 30B is formed by coating a solder on the pad 12B or/and the primary pad 22B and attaching the rigid printed circuit board 10B and the flexible printed circuit board 20B to each other. The solder layer has a primary surface 301B and a secondary surface 302B. The primary surface 301B of the solder layer 30B connects with the pad 12B of the rigid printed circuit board 10B. The secondary surface 302B of the solder layer 30B has a first area and a second area. The first area connects with the second area. The first area of the secondary surface 302B connects with the primary pad 22B of the flexible printed circuit board 20B. The second area of the secondary surface 302B does not connect with the flexible printed circuit board 20B.

With reference to FIGS. 7 to 10, in the step of removing the heat source to solidify the solder layer (S7), the solder layer 30B is solidified after the heat source is removed. In the step of forming a strengthened portion wrapping the edge of the panel of the flexible printed circuit board to obtain the combination of the flexible printed circuit board and the rigid printed circuit board (S8), a heat source 50B is used to heat the second area of the secondary surface 302B to melt the solder layer 30B partially. After the heat source 50B is removed, the solder layer 30B solidifies and a strengthened portion 31B wrapping the edge of the panel 21B of the flexible printed circuit board 20B is formed. Then the combination of the flexible printed circuit board 20B and the rigid printed circuit board 10B is obtained.

According to the method mentioned above, with reference to FIG. 10, by the forming of the strengthened portion 31B wrapping the edge of the panel 21B of the flexible printed circuit board 20B, the bonding strength between the flexible printed circuit board 20B and the rigid printed circuit board 10B is increased. Thus, the flexible printed circuit board 20B is firmly connected with the rigid printed circuit board 10B.

To sum up, with reference to FIGS. 2, 6 and 10, by forming the hole 23,23A,23B, heat is transmitted through the hole and arrives at the solder layer 30,30A,30B located between the flexible printed circuit board 20,20A,20B and the rigid printed circuit board 10,10A,10B to melt the solder layer 30,30A,30B. After the heat source is removed, the melted solder layer 30,30A,30B solidifies, and the flexible printed circuit board 20,20A,20B and the rigid printed circuit board 10,10A,10B combine with each other as a whole. In this way, there is no need to use any additional connection piece and a fixture of the same and the manufacture cost is lowered. In addition, as a result that the solder layer 30,30A,30B is very thin, the combination of the flexible printed circuit board 20,20A,20B and the rigid printed circuit board 10,10A,10B made by the method accommodates less space and has extensive applicability.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A method of making a combination of a flexible printed circuit board and a rigid printed circuit board comprising steps of:
providing a rigid printed circuit board having a panel;
providing a flexible printed circuit board having a panel and a hole formed through the panel of the flexible printed circuit board, wherein the panel of the flexible printed circuit board has a first side surface and a second side surface;
forming a solder layer located at the hole of the flexible printed circuit board and between the panel of the rigid printed circuit board and the first side surface of the panel of the flexible printed circuit board;
providing a heat source located at the second side surface of the panel of the flexible printed circuit board to heat through the hole and melt the solder layer; and
removing the heat source to solidify the solder layer to obtain a combination of the flexible printed circuit board and the rigid printed circuit board.

2. The method as claimed in claim 1, wherein the step of providing a rigid printed circuit board having a panel further comprises
locating a pad on the panel of the rigid printed circuit board;
the step of providing a flexible printed circuit board having a panel and a hole formed through the panel further comprises:
locating a primary pad on the first side surface of the panel of the flexible printed circuit board; and
forming the hole through the panel of the flexible printed circuit board and the primary pad; and
the step of forming a solder layer located at the hole of the flexible printed circuit board and between the panel of the rigid printed circuit board and the first side surface of the panel of the flexible printed circuit board comprises:
forming the solder layer located at the hole of the flexible printed circuit board and between the pad of the rigid printed circuit board and the primary pad of the panel of the flexible printed circuit board.

3. The method as claimed in claim 2, wherein the step of providing a flexible printed circuit board having a panel and a hole formed through the panel further comprises:
locating a secondary pad on the second side surface of the panel of the flexible printed circuit board; and
forming the hole through the panel of the flexible printed circuit board, the primary pad and the secondary pad; and
the step of providing a heat source located at the second side surface of the panel of the flexible printed circuit board to heat through the hole and melt the solder layer further comprises:
locating the heat source at an outer side of the secondary pad of the flexible printed circuit board.

4. The method as claimed in claim 1, wherein between the step of providing a flexible printed circuit board having a panel and a hole formed through the panel and the step of forming a solder layer located at the hole of the flexible printed circuit board and between the panel of the rigid printed circuit board and the first side surface of the panel of the flexible printed circuit board, the method further comprises a step of:
forming a heat conductive layer on a wall surrounding the hole; and
the step of forming a solder layer located at the hole of the flexible printed circuit board and between the panel of the rigid printed circuit board and the first side surface of the panel of the flexible printed circuit board comprises:
connecting the solder layer to the heat conductive layer.

5. The method as claimed in claim 2, wherein between the step of providing a flexible printed circuit board having a panel and a hole formed through the panel and the step of forming a solder layer located at the hole of the flexible printed circuit board and between the panel of the rigid printed circuit board and the first side surface of the panel of the flexible printed circuit board, the method further comprises a step of:
forming a heat conductive layer connecting with the primary pad of the flexible printed circuit board on a wall surrounding the hole; and
the step of forming a solder layer located at the hole of the flexible printed circuit board and between the panel of the rigid printed circuit board and the first side surface of the panel of the flexible printed circuit board comprises:
connecting the solder layer to the heat conductive layer by the primary pad of the flexible printed circuit board.

6. The method as claimed in claim 3, wherein between the step of providing a flexible printed circuit board having a panel and a hole formed through the panel and the step of forming a solder layer located at the hole of the flexible printed circuit board and between the panel of the rigid printed circuit board and the first side surface of the panel of the flexible printed circuit board, the method further comprises a step of:
forming a heat conductive layer on a wall surrounding the hole, wherein the heat conductive layer connects with the primary pad and the secondary pad of the flexible printed circuit board; and
the step of forming a solder layer located at the hole of the flexible printed circuit board and between the panel of the rigid printed circuit board and the first side surface of the panel of the flexible printed circuit board comprises:
connecting the solder layer to the heat conductive layer by the primary pad and the secondary pad of the flexible printed circuit board.

7. The method as claimed in claim 1, wherein the step of forming a solder layer located at the hole of the flexible printed circuit board and between the panel of the rigid printed circuit board and the first side surface of the panel of the flexible printed circuit board comprises:
forming the solder layer located at the hole of the flexible printed circuit board, wherein the solder layer has a primary surface connecting with the rigid printed circuit board and a secondary surface, wherein the secondary surface has a first area and a second area connecting with the first area, the first area of the secondary surface of the solder layer connects with the flexible printed circuit board; and
the step of removing the heat source to solidify the solder layer to obtain a combination of the flexible printed circuit board and the rigid printed circuit board further comprises:
removing the heat source to solidify the solder layer; and
forming a strengthened portion wrapping an edge of the panel of the flexible printed circuit board to obtain the combination of the flexible printed circuit board and the rigid printed circuit board, wherein the step of forming a strengthened portion further comprises:
heating the second area of the secondary surface of the solder layer to melt the solder layer partially;
solidifying the solder layer to from the strengthened portion wrapping the edge of the panel of the flexible printed circuit board to obtain the combination of the flexible printed circuit board and the rigid printed circuit board.

8. A combination of a flexible printed circuit board and a rigid printed circuit board, the combination comprising:
a rigid printed circuit board having
a panel;
a flexible printed circuit board having
a panel having
a first side surface; and
a second side surface; and
a hole formed through the panel of the flexible printed circuit board; and
a solder layer solidified between the panel of the rigid printed circuit board and the first side surface of the panel of the flexible printed circuit board, wherein the solder layer is located at the hole of the flexible printed circuit board.

9. The combination of the flexible printed circuit board and the rigid printed circuit board as claimed in claim 8, wherein the rigid printed circuit board has
a pad located on the panel of the rigid printed circuit board;
the flexible printed circuit board has
a primary pad located on the first side surface of the panel of the flexible printed circuit board; and
the hole formed through the panel and the primary pad of the flexible printed circuit board; and
the solder layer is located between the pad of the rigid printed circuit board and the primary pad of the flexible printed circuit board.

10. The combination of the flexible printed circuit board and the rigid printed circuit board as claimed in claim 9, wherein the flexible printed circuit board has
a secondary pad located on the second side surface of the panel of the flexible circuit board; and
the hole formed through the panel, the primary pad and the secondary pad of the flexible printed circuit board.

11. The combination of the flexible printed circuit board and the rigid printed circuit board as claimed in claim 8, wherein the combination of the flexible printed circuit board and the rigid printed circuit board further comprises
a heat conductive layer located on a wall surrounding the hole and the heat conductive layer connecting with the solder layer.

12. The combination of the flexible printed circuit board and the rigid printed circuit board as claimed in claim 9, wherein the combination of the flexible printed circuit board and the rigid printed circuit board further comprises
a heat conductive layer located on a wall surrounding the hole and the heat conductive layer connecting with the solder layer by the primary pad of the flexible printed circuit board.

13. The combination of the flexible printed circuit board and the rigid printed circuit board as claimed in claim 10, wherein the combination of the flexible printed circuit board and the rigid printed circuit board further comprises
a heat conductive layer located on a wall surrounding the hole, wherein two ends of the heat conductive layer respectively connect to the primary pad and the secondary pad of the flexible printed circuit board and the heat conductive layer connects with the solder layer by the primary pad of the flexible printed circuit board.

14. The combination of the flexible printed circuit board and the rigid printed circuit board as claimed in claim 8, wherein the solder layer has
a strengthened portion wrapping an edge of the flexible printed circuit board.

15. The combination of the flexible printed circuit board and the rigid printed circuit board as claimed in claim 8, wherein the panel of the flexible printed circuit board has
a flexible substrate;
an insulated layer; and
a primary conductive layer, two side surfaces of the primary conductive layer respectively connecting with the flexible substrate and the insulated layer; and
the solder layer connects with the insulated layer and the primary conductive layer of the panel of the flexible printed circuit board.

16. The combination of the flexible printed circuit board and the rigid printed circuit board as claimed in claim 9, wherein the panel of the flexible printed circuit board has
a flexible substrate;
an insulated layer; and
a primary conductive layer, two side surfaces of the primary conductive layer respectively connecting with the flexible substrate and the insulated layer; and
the primary pad of the flexible printed circuit board is attached to and electrically connects to the primary conductive layer of the panel of the flexible printed circuit board, and a side edge of the primary pad of the flexible printed circuit board connects to the insulated layer of the panel of the flexible printed circuit board.

17. The combination of the flexible printed circuit board and the rigid printed circuit board as claimed in claim 10, wherein the panel of the flexible printed circuit board has
a flexible substrate;
a primary conductive layer and a secondary conductive layer respectively located on two opposite surfaces of the flexible substrate; and
an insulated layer wrapping the flexible substrate, the primary conductive layer and the secondary conductive layer;
the primary pad of the flexible printed circuit board is attached to and electrically connects to the primary conductive layer of the panel of the flexible printed circuit board, and a side edge of the primary pad of the flexible printed circuit board connects to the insulated layer of the panel of the flexible printed circuit board; and
the secondary pad the flexible printed circuit board is attached to and electrically connects to the secondary conductive layer of the panel of the flexible printed circuit board, and a side edge of the secondary pad of the flexible printed circuit board connects to the insulated layer of the panel of the flexible printed circuit board.

18. The combination of the flexible printed circuit board and the rigid printed circuit board as claimed in claim 8, wherein the panel of the rigid printed circuit board has
a rigid substrate;
a conductive layer located on the rigid substrate; and
an insulated layer located on the conductive layer; and
the solder layer connects with the insulated layer and the conductive layer of the panel of the rigid printed circuit board.

19. The combination of the flexible printed circuit board and the rigid printed circuit board as claimed in claim 9, wherein the panel of the rigid printed circuit board has
a rigid substrate;
a conductive layer located on the rigid substrate; and
an insulated layer located on the conductive layer; and
the pad of the rigid printed circuit board is attached to and electrically connects to the conductive layer of the panel of the rigid printed circuit board, and a side edge of the pad of the rigid printed circuit board connects to the insulated layer of the panel of the rigid printed circuit board.
